(19) United States
(12) Patent Application Publication
(10) Pub. No.: US 2021/0216850 A1
(43) Pub. Date: Jul. 15, 2021

(54) STORAGE RECOMMENDER SYSTEM USING GENERATIVE ADVERSARIAL NETWORKS

(71) Applicant: EMC IP HOLDING COMPANY LLC, Hopkinton, MA (US)

(72) Inventors: Malak Alshawabkeh, Franklin, MA (US); Owen Martin, Hopedale, MA (US); Motasem Awwad, Franklin, MA (US)

(73) Assignee: EMC IP HOLDING COMPANY LLC, Hopkinton, MA (US)

(21) Appl. No.: 16/741,813

(22) Filed: Jan. 14, 2020

(51) Int. Cl. G06N 3/04; G06F 13/16; G06N 3/08; G06F 30/27

(52) U.S. Cl. CPC G06N 3/0427; G06F 13/1668; G06F 30/27; G06N 3/0454; G06N 3/088

(57) ABSTRACT

Generative adversarial networks (GAN) are used to model real IO workloads on storage nodes such as storage area networks (SANs) and network-attached storage (NAS). A GAN model is generated in situ on a storage node or in a data center using real traffic, e.g. an IO trace. The GAN model is sent to a modeling system that maintains a repository of GAN models generated from different storage nodes. An IO traffic emulator in the modeling system uses a GAN model to generate a synthetic IO stream that emulates but does not replay a real IO stream. Multiple configurations of test storage nodes may be tested with synthetic IO streams generated from GAN models and the corresponding performance measurements may be stored in a repository and used to generate recommendations, e.g. for storage node configuration to achieve a target performance level based on IO workload.

### TECHNICAL FIELD

The subject matter of this disclosure is generally related to data storage systems, and more particularly to analysis, reconfiguration, and recommendation of data storage systems.

### BACKGROUND

Storage Area Networks (SANs) and Network-Attached Storage (NAS) are examples of storage nodes that are used to maintain large data sets associated with critical functions for which avoidance of data loss and maintenance of data availability are important. Such storage nodes may simultaneously support multiple host servers and multiple host applications and be configured in failover and backup relationships. Such complexity makes it difficult to determine how a specific configuration of a storage node will perform in a specific environment, and how configuration changes will affect storage node performance in that environment.

Storage node performance could be tested with real input-output (IO) streams. However, it is usually impractical to dial-home real IO traces or test different storage node configurations with live traffic in a real data center. Consequently, testing with real IO streams is usually impractical. It is known to use a summary representation of a real workload to predict performance. For example, a statistical representation of a real workload may be used in a test lab with different storage node configurations to measure and predict performance in a real data center. However, summary representations of real workloads do not capture all the aspects of real workloads that affect storage node performance so the predictions can be inaccurate.

### SUMMARY

All examples, aspects and features mentioned in this document can be combined in any technically possible way.

In accordance with some aspects a method comprises: creating a generative adversarial network (GAN) model of input-output (IO) workload on a storage node using a real IO stream; transmitting the GAN model to a modeling system that is remote from the storage node; creating a synthetic IO stream with the GAN model in the modeling system; measuring performance of a test storage node responsive to the synthetic IO stream in the modeling system; and outputting at least one recommendation based on the measured performance. Some implementations comprise creating the GAN model with code running on the storage node. Some implementations comprise creating the GAN model with code running on a server in a data center in which the storage node is located. Some implementations comprise adding the GAN model to a repository of GAN models of IO workloads on a plurality of storage nodes. Some implementations comprise measuring performance of a plurality of test storage nodes responsive to synthetic IO streams generated from a plurality of GAN models. Some implementations comprise creating a repository of performance measurements of the test storage nodes. Some implementations comprise outputting a storage node configuration. Some implementations comprise outputting performance associated with the outputted configuration.

In accordance with some aspects an apparatus comprises: an IO traffic emulator that creates a synthetic IO stream with a generative adversarial network (GAN) model of input-output (IO) workload on a storage node created using a real IO stream; a performance evaluator that measures performance of a test storage node responsive to the synthetic IO stream; and a recommender that outputs at least one recommendation based on the measured performance. Some implementations comprise a GAN model repository comprising a plurality of GAN models of IO workloads on a plurality of storage nodes. Some implementations comprise a repository of performance measurements of a plurality of test storage nodes responsive to synthetic IO streams generated using the GAN models.

In accordance with some aspects a computer program stored on a non-transitory computer-readable storage medium, comprises: artificial intelligence, operating outside a modeling system, that creates a generative adversarial network (GAN) model of input-output (IO) workload on a storage node using a real IO stream; instructions that create a synthetic IO stream with the GAN model in the modeling system; instructions that measure performance of a test storage node responsive to the synthetic IO stream in the modeling system; and instructions that output at least one recommendation based on the measured performance. In some implementations the instructions that create the GAN model comprise code running on the storage node. In some implementations the instructions that create the GAN model comprise code running on a server in a data center in which the storage node is located. Some implementations comprise instructions that add the GAN model to a repository of GAN models of IO workloads on a plurality of storage nodes. Some implementations comprise instructions that generate a synthetic IO stream from the GAN model. Some implementations comprise instructions that measure performance of a plurality of test storage nodes responsive to synthetic IO streams generated from a plurality of GAN models. Some implementations comprise instructions that create a repository of performance measurements of the test storage nodes. In some implementations the instructions that output at least one recommendation based on the measured performance output a storage node configuration. In some implementations the instructions that output at least one recommendation based on the measured performance output performance associated with the outputted configuration.

Although no advantages should be viewed as limitations of the invention, some implementations may provide more accurate representations of real IO workloads than summary representations. Further, the synthetic IO streams generated from GAN models are not static replays of a recorded IO stream, but rather different dynamically generated synthetic IO streams that emulate real IO streams.

Other aspects, features, and implementations may become apparent in view of the detailed description and figures.

### BRIEF DESCRIPTION OF THE FIGURES

FIG. 1 illustrates a network in which GAN models of IO workloads are generated in real storage systems and a modeling system uses the GAN models for analysis, reconfiguration, and recommendation.

FIG. 2 illustrates a SAN node in which code generates a GAN model of IO workload.

FIG. 3 illustrates operation of the GAN code in greater detail.

FIG. 4 illustrates the modeling system processing GAN models.

FIG. 5 illustrates a method for generating and using GAN models for analysis, reconfiguration, and recommendation of storage systems.

### DETAILED DESCRIPTION

Aspects of the inventive concepts are described as being implemented in a data storage system that includes a host server and storage area network (SAN). Such implementations should not be viewed as limiting. Those of ordinary skill in the art will recognize that there are a wide variety of implementations of the inventive concepts in view of the teachings of the present disclosure, including but not limited to a wide variety of storage nodes and storage systems.

Some aspects, features, and implementations described herein may include machines such as computers, electronic components, optical components, and processes such as computer-implemented procedures and steps. It will be apparent to those of ordinary skill in the art that the computer-implemented procedures and steps may be stored as computer-executable instructions on a non-transitory computer-readable medium. Furthermore, it will be understood by those of ordinary skill in the art that the computer-executable instructions may be executed on a variety of tangible processor devices, i.e. physical hardware. For practical reasons, not every step, device, and component that may be part of a computer or data storage system is described herein. Those of ordinary skill in the art will recognize such steps, devices, and components in view of the teachings of the present disclosure and the knowledge generally available to those of ordinary skill in the art. The corresponding machines and processes are therefore enabled and within the scope of the disclosure.

The terminology used in this disclosure is intended to be interpreted broadly within the limits of subject matter eligibility. The terms “logical” and “virtual” are used to refer to features that are abstractions of other features, e.g. and without limitation abstractions of tangible features. The term “physical” is used to refer to tangible features that possibly include, but are not limited to, electronic hardware. For example, multiple virtual computers could operate simultaneously on one physical computer. The term “logic” is used to refer to special purpose physical circuit elements, firmware, software, computer instructions that are stored on a non-transitory computer-readable medium and implemented by multi-purpose tangible processors, and any combinations thereof.

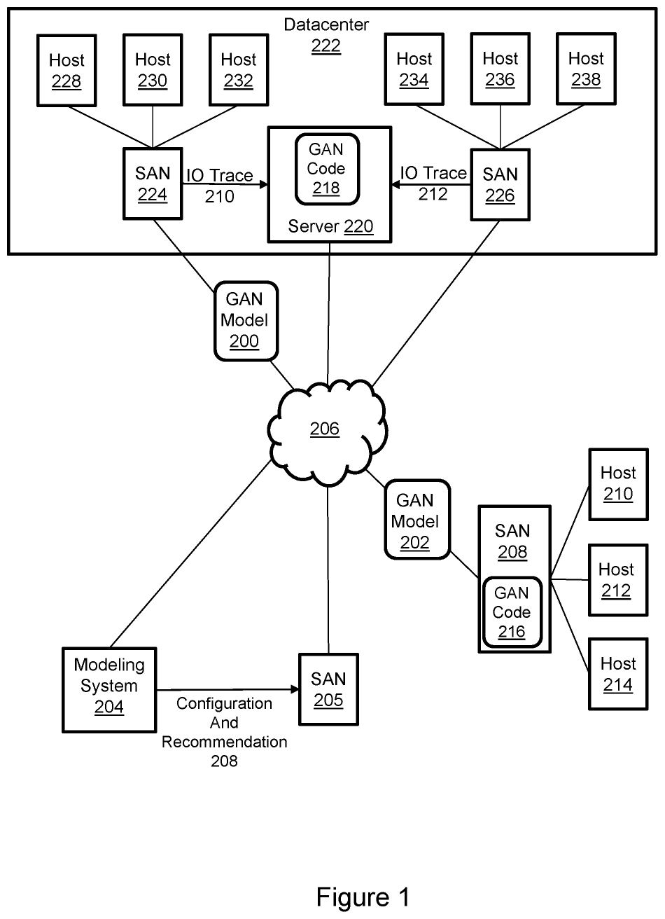

FIG. 1 illustrates a network in which generative adversarial networks (GANs) are used to generate GAN models 200, 202 of workloads in real storage systems. The GAN models provide a better representation of real workloads than summary representations. A remote modeling system 204 uses the GAN models for analysis, reconfiguration, and recommendation, e.g. to predict response times for computing satisfactory configurations of a planned SAN 205.

In one implementation a SAN 208 that supports hosts 210, 212, 214 is modeled. GAN code 216 running on the SAN 208 generates a GAN model 202 of the real IO workload on SAN 208. That workload may include, for example, the IOs between SAN 208 and the supported hosts 210, 212, 214 and IOs between SAN 208 and a SAN 226 to which snapshots are sent. The GAN model 202 is sent from SAN 208 to the modeling system 204 via a network 206. The modeling system 204 may use the GAN model 202 to generate configuration and recommendation information 208, as will be explained in greater detail below.

In another implementation GAN code 218 running on a server 220 in a datacenter 222 is used to generate a GAN model 200. The datacenter 222 includes a SAN 224 that supports hosts 228, 230, and 232, and a SAN 226 that supports hosts 234, 236, and 238. The GAN code 218 may generate the GAN model 200 based on the real workload of one or both SANs 224, 226 as indicated by IO traces 210, 212. For purposes of explanation, in a context in which analysis, reconfiguration, and recommendation for individual SANs is being generated, it is assumed that GAN model 200 is a model of the real workload of SAN 224 alone. The GAN model 200 is sent from server 220 to the modeling system 204 via the network 206. The modeling system 204 may use the GAN model 200 to generate the configuration and recommendation information 208.

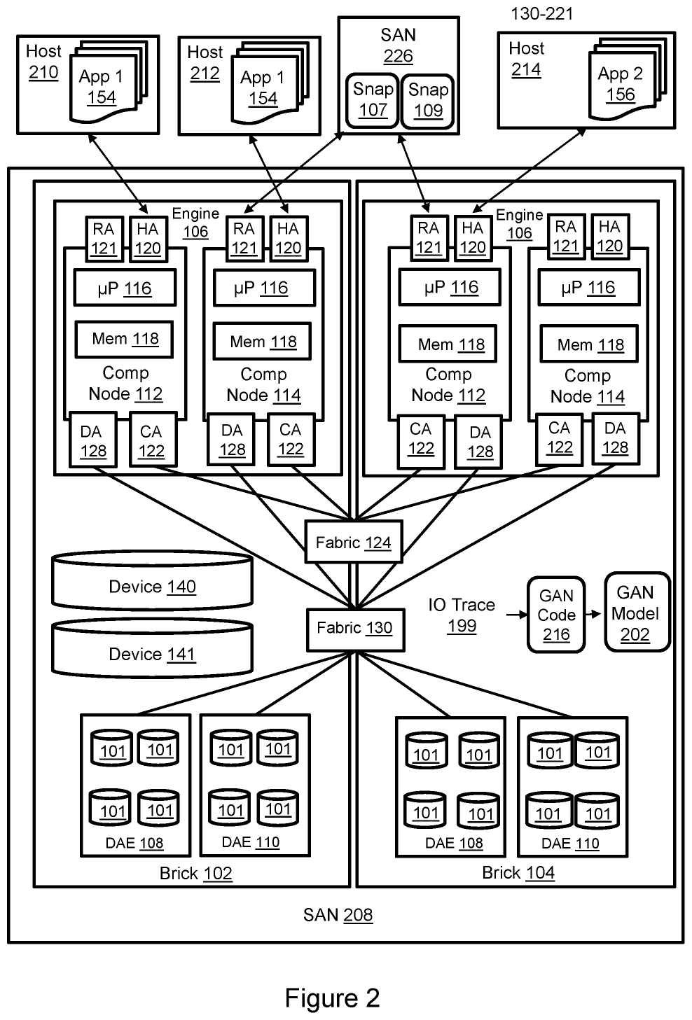

FIG. 2 illustrates SAN 208 in greater detail. The SAN 208, which may be referred to as a storage array, includes one or more bricks 102, 104. Each brick includes an engine 106 and one or more drive array enclosures (DAEs) 108, 110. Each DAE includes managed drives 101 of one or more technology types. Examples may include, without limitation, solid state drives (SSDs) such as flash and hard disk drives (HDDs) with spinning disk storage media. Each engine 106 includes a pair of interconnected computing nodes 112, 114, which may be referred to as “storage directors.” Each computing node includes resources such as at least one multi-core processor 116 and local memory 118. The processor may include central processing units (CPUs), graphics processing units (GPUs), or both. The local memory 118 may include volatile random-access memory (RAM) of any type, non-volatile memory (NVM) such as storage class memory (SCM), or both. Each computing node includes one or more host adapters (HAs) 120 for communicating with the hosts 150, 152. Each host adapter has resources for servicing IOs, e.g. processors, volatile memory, and ports via which the hosts may access the SAN. Each computing node also includes a remote adapter (RA) 121 for communicating with other storage systems such as SAN 226. Each computing node also includes one or more drive adapters (DAs) 122 for communicating with the managed drives 101 in the DAEs 108, 110. Each drive adapter has resources for servicing IOs, e.g. processors, volatile memory, and ports via which the computing node may access the DAEs. Each computing node may also include one or more channel adapters (CAs) 122 for communicating with other computing nodes via an interconnecting fabric 124. Each computing node may allocate a portion or partition of its respective local memory 118 to a shared memory that can be accessed by other computing nodes, e.g. via direct memory access (DMA) or remote DMA (RDMA). The paired computing nodes 112, 114 of each engine 106 provide failover protection and may be directly interconnected by communication links. An interconnecting fabric 130 enables implementation of an N-way active-active backend. In some implementations every DA in the SAN can access every managed drive 101.

Data associated with host applications 154, 156 running on the hosts 210, 212, 214 is maintained on the managed drives 101. The managed drives 101 are not discoverable by the hosts but the SAN creates logical storage devices 140, 141 that can be discovered and accessed by the hosts. Without limitation, the logical storage devices may be referred to as “source devices” or simply “devices” for snap creation, and more generally as production volumes, production devices, or production “LUNs,” where LUN (Logical Unit Number) is a number used to identify logical storage volumes in accordance with the Small Computer System Interface (SCSI) protocol. In the illustrated example logical storage device 140 is used by instances of host application 154 for storage of host application data and logical storage device 141 is used by instances of host application 156 for storage of host application data. From the perspective of the hosts each logical storage device is a single drive having a set of contiguous fixed-size logical block addresses (LBAs) on which data used by instances of the host application resides. However, the host application data is stored at non-contiguous addresses on various managed drives 101.

To service IOs from instances of a host application the SAN 208 maintains metadata that indicates, among various things, mappings between LBAs of the logical storage devices 140, 141 and addresses with which extents of host application data can be accessed from the shared memory and managed drives 101. In response to a data access command from an instance of one of the host applications to READ data from the production volume 140 the SAN uses the metadata to find the requested data in the shared memory or managed drives. When the requested data is already present in memory when the command is received it is considered a “cache hit.” When the requested data is not in the shared memory when the command is received it is considered a “cache miss.” In the event of a cache miss the accessed data is temporarily copied into the shared memory from the managed drives and used to service the IO, i.e. reply to the host application with the data via one of the computing nodes. In the case of a WRITE to one of the production volumes the SAN copies the data into the shared memory, marks the corresponding logical storage device location as dirty in the metadata, and creates new metadata that maps the logical storage device address with a location to which the data is eventually written on the managed drives. READ and WRITE “hits” and “misses” occur depending on whether the stale data associated with the IO is present in the shared memory when the IO is received.

SAN 226 maintains replicas or backups of the logical devices 140, 141. Snap 107 and snap 109 respectively are created for the logical devices 140, 141 in furtherance of maintaining the replicas or backups remotely on SAN 226. Each snap is a consistent point-in-time persistent storage copy of a storage object such as source devices 140, 141. Multiple snaps may be generated over time, and each snap may be an incremental copy that only represents changes to the source device since some prior point in time, e.g. and without limitation since creation of the previous snap. For example, a first snap could be created at time t=0 and a second snap could be created at time t=1, where the second snap represents only the changes since the first snap was created. A snap that is a complete copy of the source device at some point in time may be referred to as a clone. Clones may be created to provide prior point in time versions of the source device where the source device is updated with each change. A wide variety of different types of snaps may be implemented, and the term snap is used herein to refer to both incremental and complete copies.

In view of the description above it will be understood that the IO traffic associated with SAN 208 may be complex. IOs from the hosts may vary in size, frequency, and other aspects depending on time of day, day of week, host application, and other factors. Further, snap creation can create IOs that are dissimilar to IOs from the hosts. In order to generate the GAN model 202 an IO trace 199 for a selected time period is captured and stored by the SAN 208. The IO trace 199 is provided to the GAN code 216, which may run on one or more of the computing nodes. The GAN code 216 trains and outputs the GAN model 202 using the IO trace.

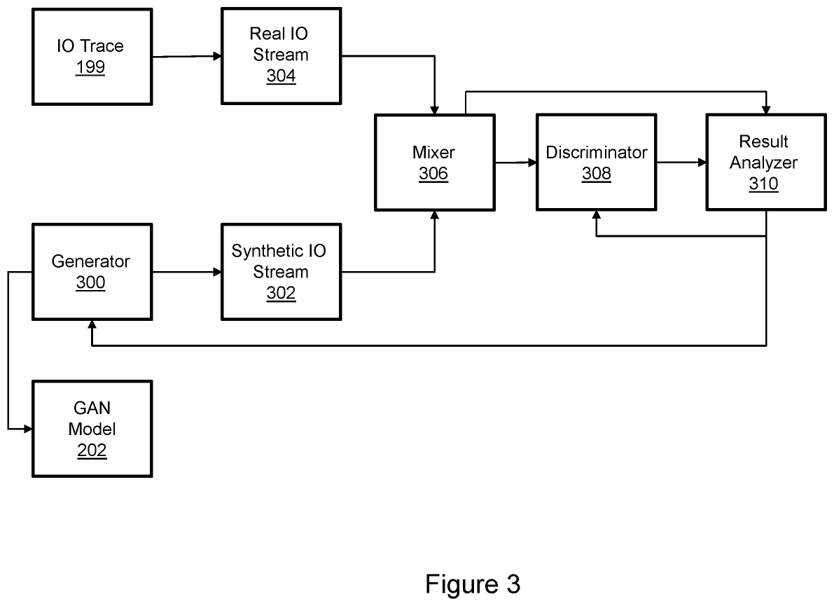

FIG. 3 illustrates operation of the GAN code 216 (FIGS. 1 and 2). A real IO stream 304 from the IO trace 199 and a synthetic IO stream 302 from a generator 300 are inputted to a mixer 306. The generator 300 is an artificial intelligence (AI) program that is configured to learn to create a synthetic IO stream 302 that is similar to, or even indistinguishable from, the real IO stream 304. The similarity does not extend to the contents of the data but includes similarity in size, frequency, and type of IOs (e.g. Reads and Writes and snaps) as a function of time of day, day of week, and other aspects. The generator 300 may use random inputs to introduce random modifications to the generated synthetic IOs. The mixer 306 interleaves or randomly selects IOs to be provided to a discriminator 308. The discriminator 308 is an AI program that is configured to distinguish real IOs from synthetic IOs. The discriminator processes each IO received from the mixer and outputs an indication of whether the processed IO is classified by the AI as a real IO or a synthetic IO. The output is not necessarily binary. For example, the output may indicate a probability of the processed IO being real or synthetic. A result analyzer 310 receives information from the mixer indicating whether each IO is real or synthetic. That information is used by the result analyzer 310 to determine whether the discriminator 308 correctly or incorrectly classified each processed IO. The accuracy of the classification by the discriminator is provided to both the discriminator and the generator as feedback from the result analyzer. The feedback is used by the generator and the discriminator to train their respective models, e.g. to learn to generate more realistic synthetic IOs (in the case of the generator) and to more accurately distinguish synthetic IOs from real IOs (in the case of the discriminator). The generator and discriminator are in an adversarial relationship because the discriminator improves its ability to correctly classify IOs contemporaneous with the generator improving its ability to generate synthetic IOs that cannot be distinguished from real IOs. When the generator's model is sufficiently trained it is outputted as GAN model 202. GAN code 218 (FIG. 1) may function in the same way except running on a server.

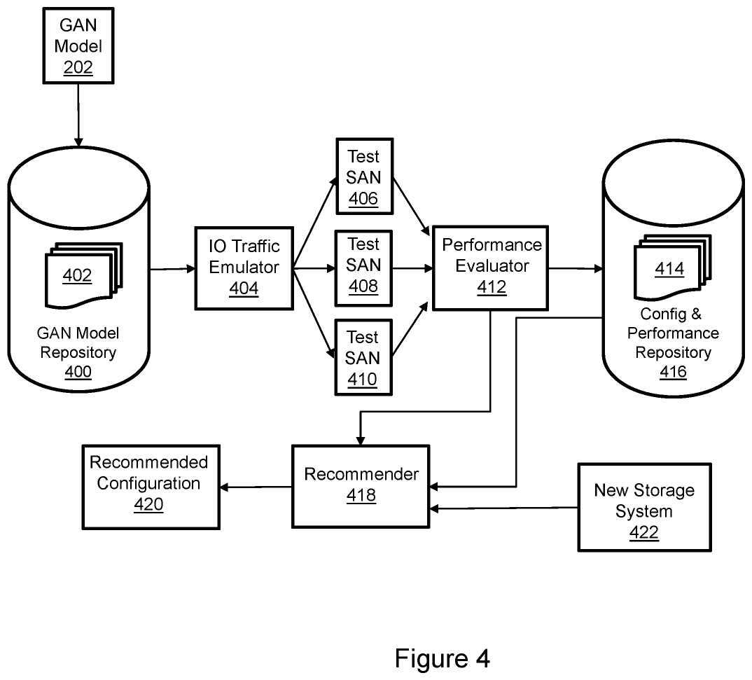

FIG. 4 illustrates features of the modeling system 204 (FIG. 1). The GAN model 202 received from GAN code 216 (FIGS. 1 and 2) is added to a GAN model repository 400 that includes a collection 402 of GAN models. A GAN model selected from the collection 402, such as GAN model 202, is loaded on an IO traffic emulator 404. The IO traffic emulator uses the loaded GAN model to generate a synthetic IO stream that emulates the real IO stream with which the selected GAN model was trained. The synthetic stream is not a playback of the real IO stream with which the model was trained but rather a realistic emulation of the real IO stream, e.g. in terms of IO size and type as a function of time. Random data may be used for the synthetic IOs. The synthetic IO stream is provided to test SANs 406, 408, 410 (or any type of storage node or storage system) having different configurations. A performance evaluator 412 measures and evaluates the performance of each test SAN with the synthetic IO stream. Records 414 of the performance measurements and evaluations are stored in a repository 416. The performance measurements and evaluations (e.g. directly from the performance evaluator) may be used by a recommender 418 to generate a recommended configuration 420 for the SAN from which the selected GAN model was generated. For example, the recommender may determine that a specific test SAN configuration most efficiently satisfies target performance criteria. Further, the records 414 of performance measurements and evaluations for multiple GAN models and test SANs may be used by the recommender to generate a recommended configuration 420 for a new storage system 422, e.g. a new SAN that will have a workload similar to one of the records in the repository 416.

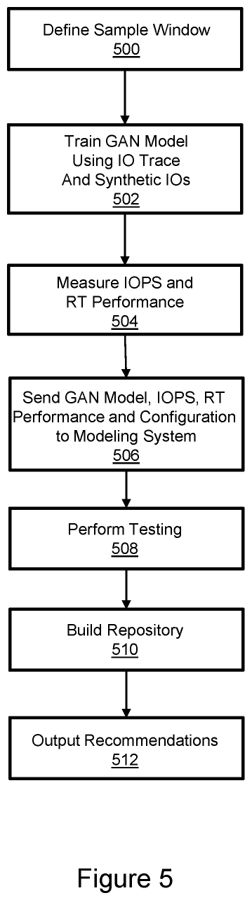

FIG. 5 illustrates a method for generating and using GAN models to generate recommendations for storage systems. Step 500 is to define a sample window for capture of the IO trace. The GAN model is trained using the IO trace and synthetic IOs created by the generator as indicated in step 502. IOs per second (IOPS) and response time (RT) performance of the storage node are measured for the sample window as indicated in step 504. Storage node configuration information may also be captured, e.g. number of bricks, details about the computing nodes and managed drives, software versions etc. The trained GAN model, performance information, and configuration information are sent from the storage node to the modeling system as indicated in step 506. As indicated in step 508, the modeling system uses the GAN model, performance information, and configuration information to perform testing with test storage nodes in the lab. The results of the testing are used to build a repository as indicated in step 510. The results of testing with one or multiple GAN models are used to output recommendations as indicated in step 512.

Specific examples have been presented to provide context and convey inventive concepts. The specific examples are not to be considered as limiting. A wide variety of modifications may be made without departing from the scope of the inventive concepts described herein. Moreover, the features, aspects, and implementations described herein may be combined in any technically possible way. Accordingly, modifications and combinations are within the scope of the following claims.

What is claimed is:

1. A method comprising:
creating a generative adversarial network (GAN) model of input-output (IO) workload on a storage node using a real IO stream;
transmitting the GAN model to a modeling system that is remote from the storage node;
creating a synthetic IO stream with the GAN model in the modeling system;
measuring performance of a test storage node responsive to the synthetic IO stream in the modeling system; and
outputting at least one recommendation based on the measured performance.

2. The method of claim 1 comprising creating the GAN model with code running on the storage node.

3. The method of claim 1 comprising creating the GAN model with code running on a server in a data center in which the storage node is located.

4. The method of claim 1 comprising adding the GAN model to a repository of GAN models of IO workloads on a plurality of storage nodes.

5. The method of claim 4 comprising measuring performance of a plurality of test storage nodes responsive to synthetic IO streams generated from a plurality of GAN models.

6. The method of claim 5 comprising creating a repository of performance measurements of the test storage nodes.

7. The method of claim 1 wherein outputting at least one recommendation comprises outputting a storage node configuration.

8. The method of claim 7 wherein outputting at least one recommendation comprises outputting performance associated with the outputted configuration.

9. An apparatus comprising:
an IO traffic emulator that creates a synthetic IO stream with a generative adversarial network (GAN) model of input-output (IO) workload on a storage node created using a real IO stream;
a performance evaluator that measures performance of a test storage node responsive to the synthetic IO stream; and
a recommender that outputs at least one recommendation based on the measured performance.

10. The apparatus of claim 9 comprising a GAN model repository comprising a plurality of GAN models of IO workloads on a plurality of storage nodes.

11. The apparatus of claim 10 comprising a repository of performance measurements of a plurality of test storage nodes responsive to synthetic IO streams generated using the GAN models.

12. A computer program stored on a non-transitory computer-readable storage medium, comprising:
artificial intelligence, operating outside a modeling system, that creates a generative adversarial network (GAN) model of input-output (IO) workload on a storage node using a real IO stream;
instructions that create a synthetic IO stream with the GAN model in the modeling system;
instructions that measure performance of a test storage node responsive to the synthetic IO stream in the modeling system; and
instructions that output at least one recommendation based on the measured performance.

13. The computer program stored on a non-transitory computer-readable storage medium of claim 12 wherein the instructions that create the GAN model comprise code running on the storage node.

14. The computer program stored on a non-transitory computer-readable storage medium of claim 12 wherein the instructions that create the GAN model comprise code running on a server in a data center in which the storage node is located.

15. The computer program stored on a non-transitory computer-readable storage medium of claim 12 comprising instructions that add the GAN model to a repository of GAN models of IO workloads on a plurality of storage nodes.

16. The computer program stored on a non-transitory computer-readable storage medium of claim 15 comprising instructions that generate a synthetic IO stream from the GAN model.

17. The computer program stored on a non-transitory computer-readable storage medium of claim 16 comprising instructions that measure performance of a plurality of test storage nodes responsive to synthetic IO streams generated from a plurality of GAN models.

18. The computer program stored on a non-transitory computer-readable storage medium of claim 17 comprising instructions that create a repository of performance measurements of the test storage nodes.

19. The computer program stored on a non-transitory computer-readable storage medium of claim 12 wherein the instructions that output at least one recommendation based on the measured performance output a storage node configuration.

20. The computer program stored on a non-transitory computer-readable storage medium of claim 19 wherein the instructions that output at least one recommendation based on the measured performance output performance associated with the outputted configuration.
